(19) United States
(12) Patent Application Publication
(10) Pub. No.: US 2010/0049465 A1
(43) Pub. Date: Feb. 25, 2010

(54) TESTABLE ELECTRONIC DEVICE FOR WIRELESS COMMUNICATION

(75) Inventors: Jose De Jesus Pineda De Gyvez, Eindhoven (NL); Alexander G. Gronthoud, Eindhoven (NL); Ralf L.J. Roovers, Wommelgem (BE); Noman Hai, Karachi (PK)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/526,852

(22) PCT Filed: Feb. 21, 2008
(86) PCT No.: PCT/IB08/50625

§ 371 Date: Aug. 12, 2009

(30) Foreign Application Priority Data
Feb. 23, 2007 (EP) 07102944.1

(51) Int. Cl. G01M 19/00; G01R 31/00

(52) U.S. Cl. 702/122; 324/500

(57) ABSTRACT

An electronic device is disclosed comprising a transceiver stage (140) for communicating signals between the electronic device and a further device; and a baseband processor arrangement (120) implementing a built-in self test arrangement for testing the transceiver channels of the electronic device (100). The built-in self test arrangement further comprises a plurality of records, each record comprising predetermined response deviations to different test signals caused by a parametric fault; and means for selecting those records from the plurality of records for which the predetermined response deviation corresponds to the deviation of the received response. The present invention is based on the realization that a deviation of a response to a test signal from an expected value is dependent on specific parametric faults in specific components in the test signal path and, in addition, on the shape of the test signal. This information is stored in the BIST arrangement and is used to identify a parametric fault, if present, by subjecting the electronic device to a series of test signals.

The present invention relates to an electronic device comprising a transceiver stage for communicating signals between the electronic device and a further device; and a baseband processor arrangement implementing a built-in self test arrangement for, in a test mode forwarding a test signal to the transceiver stage, receiving a response to the test signal and determining, for the response, the deviation from the expected response to the test signal.

The present invention further relates to a method for testing such an electronic device.

The testing of wireless communication electronic devices that operate in a high frequency range such as the radio frequency (RF) range is not without practical problems. For instance, most test apparatuses for testing integrated circuits are not capable of providing the high-frequency test patterns for testing the RF parts of the wireless communication. This drawback may be overcome by buying dedicated test equipment, but this solution is commonly unsatisfactory because of the high cost of such dedicated equipment.

For this reason, built-in self test (BIST) solutions have been published in which a test signal generated at the baseband level is forwarded to the transmitter and looped back into the receiver, e.g. via the use of a fibre optic cable or looped back through the air. Examples of such approaches can be found in ‘A built-in loopback test methodology for RF transceiver circuits using embedded sensor circuits’ by S. Bhattacharya et al. in Proc. of the 13^{th} Asian Test Symposium, ATS 2004, pages 68-73, and in ‘RF-BIST: Loopback spectral signature analysis’ by D. Lupea et al. in Proc. of the Design, Automation and Test in Europe Conference and Exhibition, DATE 2003, pages 478-483.

Advances in IC development, e.g. the emergence of Systems-on-Chip (SoCs) has led to a reduction of hardware required to implement the high frequency part of the electronic device because some of this functionality may be implemented by a baseband processor such as a SoC. However, some dedicated high frequency hardware remains present in such electronic devices because the baseband processor cannot implement the functionality of this dedicated hardware with sufficient quality. Consequently, even in such an electronic device there is a need for a satisfactory test solution for the high frequency parts of the device.

The paper ‘Mixed Loopback BIST for RF Digital Transceivers’ by Jerzy Dabrowski et al. in Proceedings of the 19^{th} IEEE Conference on Defect and Fault Tolerance in VLSI Systems, pages 220-228, 2004 (ISBN 0-7695-2241-6) discloses a BIST arrangement in which the test pattern generator and response analyzer are implemented on the baseband processor. The test signal is looped back from the transmitter to the receiver, i.e. at the output of the digital transceiver. The behaviour of the components in the signal path between the baseband processor and the transceiver stage, such as a mixer or a low noise amplifier, is estimated from the determined noise figure of the response to the test signal using the Friis formula.

It has been found that the fault coverage of the prior art methods is unsatisfactory. In addition, these methods do not target the detection of so-called parametric faults, i.e. faults that arise from a spread in the process parameters of the integrated circuit components of the electronic device of the opening paragraph.

The present invention seeks to provide an electronic device according to the opening paragraph having a built-in self-test arrangement that facilitates improved detection of parametric faults.

The present invention also seeks to provide a method for testing an electronic device according to the opening paragraph that facilitates improved detection of parametric faults.

According to a first aspect of the present invention, there is provided an electronic device according to the opening paragraph, wherein the built-in self test arrangement further comprises a plurality of records, each record comprising predetermined response deviations to different test signals caused by a parametric fault; and means for selecting those records from the plurality of records for which the predetermined response deviation corresponds to the deviation of the received response.

The present invention is based on the fact that different parametric faults give rise to different deviations in the responses to selected test signals. Typically, only some particular parametric faults will cause the response to a particular test signal to deviate from the expected response beyond a predefined threshold. In other words, the deviation of the response from its expected shape is dependent on both the applied test signal and the nature of the parametric fault in the signal loop from and to the baseband processor. Hence, by storing records of these relationships, with each record representing a specific parametric fault, onto the baseband processor architecture, e.g. in a number of look-up tables or any other suitable data storage, the determination of the deviation of the response and subsequent selection of the appropriate records provided valuable information about which parametric fault is present in the electronic device. This information can be used to improve the manufacturing process of the electronic device.

Because the selection of records may comprise more than one record, the built-in self test arrangement may be arranged to forward a further test signal to the transceiver stage; receive a further response to the further test signal; determine, for the further response, a further deviation from the expected further response to the further test signal; and deleting those records from the selection of records that comprise a predetermined deviation from the expected response to the further test signal that is different to the determined further deviation. The provision of one or more further test signals is intended to narrow down the selection of records to a single record, for the purpose of isolating the parametric fault present in the electronic device.

In an embodiment, the electronic device comprises a frequency upconversion stage for upconverting the frequency of signals from the baseband processor to the transceiver stage; a frequency downconversion stage for downconverting the frequency of signals from the transceiver stage to the baseband processor; and a loopback path from a part of the frequency upconversion stage to a corresponding part of the frequency downconversion stage. The provision of a loopback path that bypasses at least a part of the signal paths from and to the transceiver end, e.g. the antenna, has the advantage that the test signal travels through less components in the signal path, which reduces the number of possible locations of a potential parametric fault, thus facilitating the detection of the location of the fault.

Preferably, the frequency upconversion stage comprises an upsampling unit, a filter, a signal modulator and an amplifier coupled in series; the frequency downconversion stage comprises an amplifier, a signal demodulator, a filter and a downsampling unit coupled in series; and the electronic device comprises at least one of the following loopback paths: a first loopback path coupling the output of the amplifier in the upconversion stage to the input of the amplifier in the downconversion stage; a second loopback path coupling the output of the amplifier in the upconversion stage to the input of the signal demodulator in the downconversion stage; and a third loopback path coupling the output of the filter in the upconversion stage to the input of the filter in the downconversion stage.

The use of different loopback paths that bypass different parts of the upconversion and downconversion stages further improves the test resolution, because the selection of different loopback paths further facilitates the detection of the location of a fault. Typically, a loopback path can be placed between any two components that are arranged to respectively generate and receive signals having corresponding frequency characteristics.

According to another aspect of the present invention, there is provided a method for testing an electronic device according to the opening paragraph, the method comprising forwarding a test signal to the transceiver stage; receiving a response to the test signal; determining, for the response, the deviation from the expected response to the test signal; providing a plurality of records, each record comprising predetermined response deviations to different test signals caused by a parametric fault; and selecting those records from the plurality of records for which the predetermined response deviation corresponds to the deviation of the received response.

The method of the present invention defines the steps executed by the electronic device of the present invention in self-test mode, and benefits from the same advantages as mentioned for the electronic device of the present invention.

The invention is described in more detail and by way of non-limiting examples with reference to the accompanying drawings, wherein:

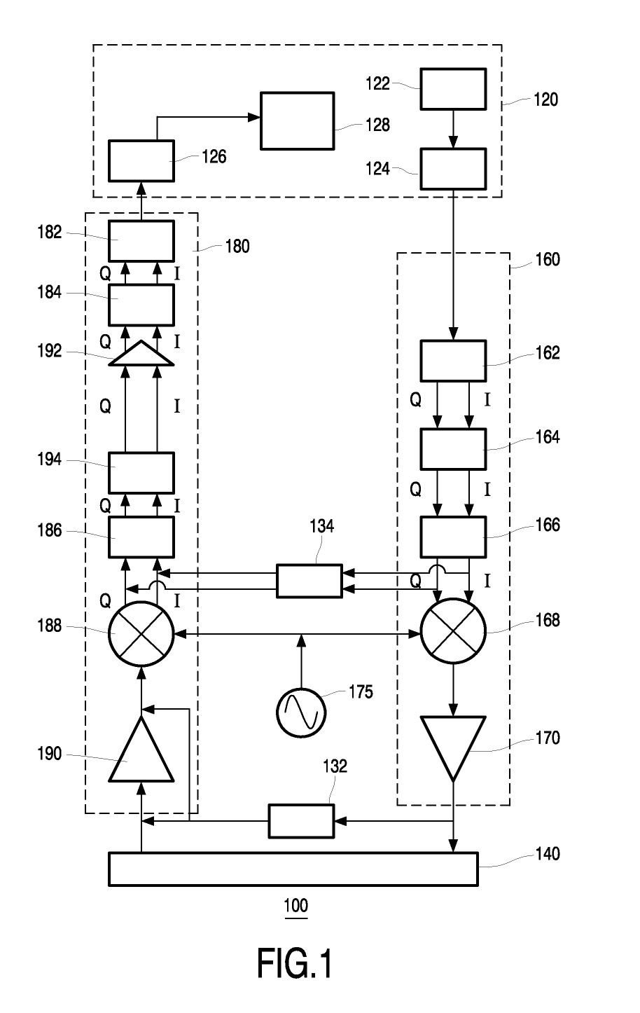

FIG. 1 depicts an embodiment of an electronic device of the present invention;

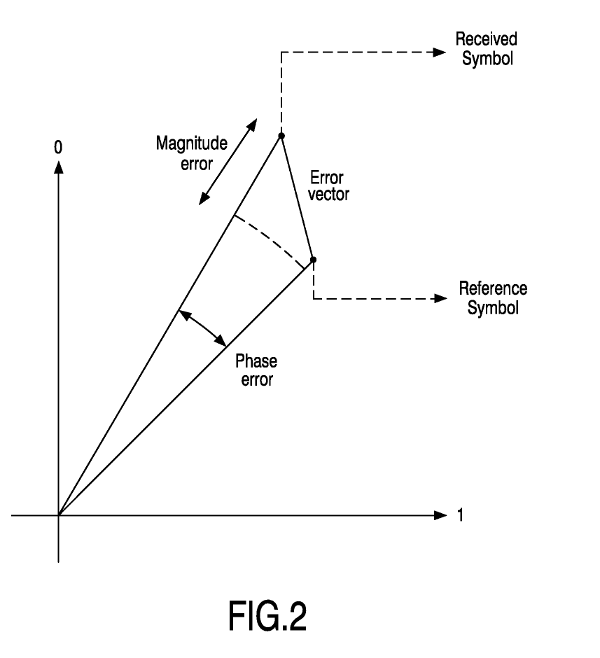

FIG. 2 explains the concept of the error vector magnitude (EVM) of a received symbol;

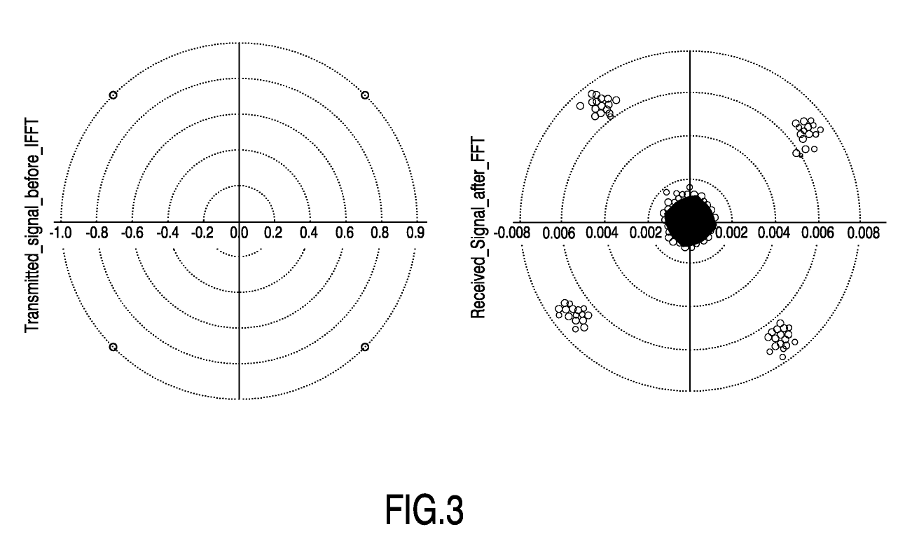

FIG. 3 is a constellation map of the transmitted and received symbols during self-test of the electronic device of the present invention; and

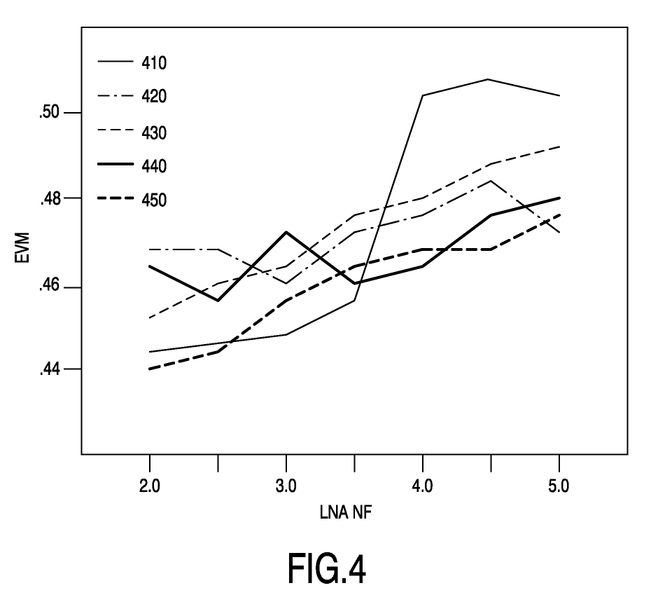

FIG. 4 depicts the test signal dependent behaviour of a parametric fault in terms of EVM;

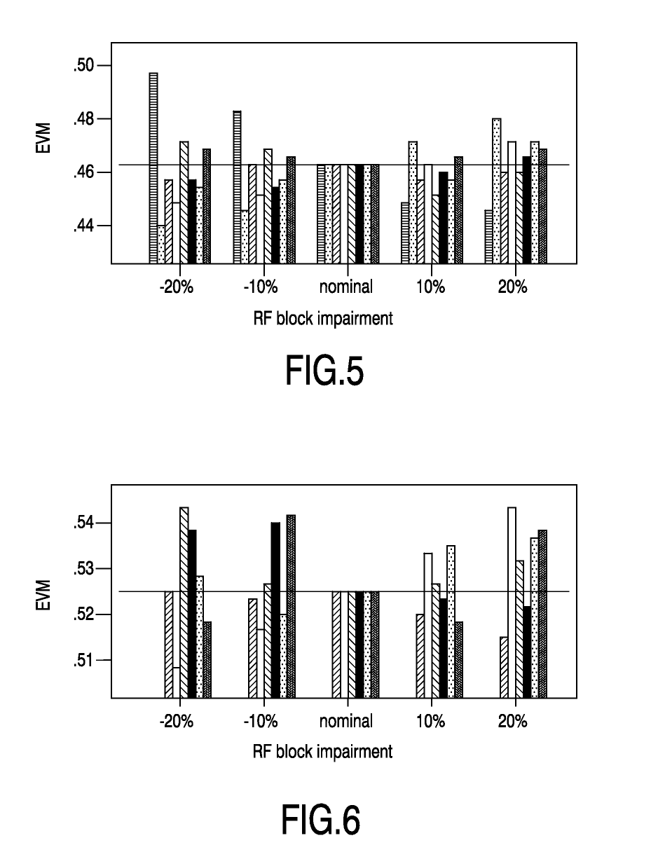

FIG. 5 depicts the parametric fault-induced EVM behaviour of various components of the electronic device when using a loopback path in the electronic device of the present invention; and

FIG. 6 depicts the parametric fault-induced EVM behaviour of various components of the electronic device when using another loopback path in the electronic device of the present invention.

It should be understood that the Figures are merely schematic and are not drawn to scale. It should also be understood that the same reference numerals are used throughout the Figures to indicate the same or similar parts.

The electronic device 100 shown in FIG. 1 has a baseband processor architecture 120 implementing a BIST arrangement coupled to an RF front end 140 via an upconversion stage 160 and a downconversion stage 180. The exact implementation of the upconversion stage 160 and the downconversion stage 180 is not critical to the present invention. By way of non-limiting example, the BIST arrangement of the baseband processor architecture comprises a test pattern generator 122 that provides a test pattern, or test signal, to an inverse fast Fourier transformation (IFFT) function 124 in the test mode of the electronic device 100. The IFFT function 124 is arranged to generate a complex signal, i.e. a symbol, and is coupled to a stage 162 for converting the complex signal from IFFT function 124 into an in-phase quadrature signal. This signal is passed onto an upsampling stage 164 and a filter 166, after which the I and Q components of the signal are modulated by mixer 168 under control of a local oscillator 175 and amplified by power amplifier 170 before it is transmitted by the RF front end 140.

A signal received by the RF front end 140 is provided to low noise amplifier 190 and forwarded to demodulating mixer 188 for the generation of a in-phase quadrature signal. In case the respective frequencies of the signals received and transmitted by the RF front end 140 are identical, the demodulating mixer 188 may be controlled by the same local oscillator 175 that is arranged to control modulating mixer 168. Otherwise, an additional oscillator (not shown) is required. The I and Q components of the generated in-phase (I) quadrature (Q) signal are forwarded to a filter 186 and routed through a DC offset stage 194 before being passed onto an analog-to-digital converter 192. The digitized in-phase quadrature signal is downsampled in downsampling stage 184 before being converted into a complex signal by stage 182.

By way of non-limiting example, the BIST block of the baseband processor architecture 120 further comprises a fast Fourier transformation (FFT) function 126 for deriving the frequency components, i.e. the received symbol, of the complex representation of the in-phase quadrature signal, and a quadrature phase shift key (QPSK) calculation block 128 for calculating the EVM of the received symbol as a possible implementation of a way of calculating the deviation of the received response to the test signal from its intended shape. However, it will be appreciated that other known ways of calculating a deviation from an expected test response are equally suitable to be used by the BIST arrangement of the present invention.

FIG. 2 explains in more detail how the EVM is calculated. The EVM is the calculation of the magnitude and phase difference between a reference symbol, i.e. the test signal injected into the upconversion stage, and the received symbol, i.e. the response received from the downconversion stage. It will be appreciated that for a golden device, i.e. a fault-free device known to behave according to specification, the EVM will be negligible because the received symbol will be, more or less, identical to the transmitted symbol. Consequently, the detection of a non-negligible EVM, is an indication of the presence of a parametric fault in one or more of the components in the looped-back signal path of the test signal.

FIG. 3 gives an example of a constellation diagram obtained in the test mode of the electronic device 100. The left-hand diagram depicts the constellation points of the symbols inserted into the upconversion stage 160, whereas the right-hand diagram depicts the constellation points of the symbols received from the downconversion stage 180. It is clear from the right-hand diagram that a substantial deviation exists between the transmitted symbols and some of the received symbols.

The present invention is based on the realization that specific parametric faults in specific components of the test signal path can cause a deviation of the test response from its intended shape that is dependent of the shape of the test signal, e.g. bit pattern, injected into the test signal path. This is for instance demonstrated in FIG. 4, where EVM response of the low-noise amplifier 190 to different test signals as a function of different noise figures (in dB) of the low-noise amplifier 190 is given. The noise figure of the of the low-noise amplifier 190 is used as an indicator of the presence of a parametric fault in the low-noise amplifier 190. Test signal 410 is an all ‘0’ bit pattern, test signal 420 is a bit pattern comprising 75% ‘0’s, test signal 430 is a bit pattern comprising 25% ‘0’s, test pattern 440 is an all ‘1’ bit pattern and test signal 450 is a random bit pattern. It will be clear that the parametric fault in the low-noise amplifier 190, which is expressed in terms of its noise figure, have a strong influence on its EVM response to different test signals.

Moreover, different components in the test signal path have a different EVM characteristic when their behaviour deviates from the intended (nominal) behaviour. This is demonstrated in FIG. 5, where the simulated EVM behaviour of several components in the test signal path at various modified performance levels relative to the nominal performance of these components is given. A test signal comprising a random bit pattern has been used. The displayed component performance in FIG. 5 at the various performance levels is, from left to right, the gain of the low-noise amplifier 190, the noise figure of the low-noise amplifier 190, the gain of demodulating mixer 188, the noise figure of demodulating mixer 188, the gain imbalance of the modulating mixer 168, the phase imbalance of the modulating mixer 168, the loss in filter 186 and the DC offset in offset block 194. The horizontal line depicts the EVM response of the golden device to this test signal.

The amount of deviation of the measured EVM response from the EVM response of the golden device can be seen as a confidence level indicator, i.e. an indicator expressing the likelihood of a fault being detected. As can be seen from FIG. 5, the largest deviation from the EVM response of the golden device is obtained for deviations from the nominal values of the gain and noise figure of the low-noise amplifier 190. For instance, at a gain level of −20% the nominal gain, the low noise amplifier 190 produces an EVM response to the random bit pattern of over 0.49, whereas the golden device EVM response is around 0.46. Similarly, at an increased noise figure level of +20% with respect to the nominal noise figure level, the EVM response of the low noise amplifier 190 again shows the largest deviation from the EVM response of the golden device.

This is not surprising, because it is well-known that the noise figure of the low noise amplifier 190 tends to dominate the noise figure behaviour of a receiver. This, however, can cause the masking of faults in components in the downconversion stage 180 between the low noise amplifier 190 and the baseband processor arrangement 120. For this reason, the electronic device 100 of the present invention has been equipped with a number of loopback paths, such that components that have a tendency of dominating a particular signal characteristic, e.g. a noise figure, can be bypassed, thus enhancing the detectability of parametric faults in the components included in the test signal path.

Returning to FIG. 1, the electronic device 100 has a first loopback path coupling the output of the power amplifier 170 to the input of the low noise amplifier 190 via test attenuator 132, a second loopback path coupling the output of the power amplifier 170 to the input of the demodulating mixer 188 via test attenuator 132, thus bypassing the low noise amplifier 190, and a third loopback path coupling the output of filter 166 to the input of filter 186 via test attenuator 134. The test attenuators 132 and 134 can be activated in the test mode by the BIST arrangement implemented by the baseband processor arrangement 120. Activation of a test attenuator implies the selection of the loopback path. It will be appreciated that the first and second loopback path share test attenuator 132 by way of example only. An implementation using separate test attenuators is equally feasible, and other or additional loopback paths may be placed between the upconversion stage 160 and the downconversion stage 180.

The data depicted in FIG. 5 has been collected using the loopback path from the output of the power amplifier 170 to the input of the low-noise amplifier 190. The effect of bypassing one or more components by using a different loopback path is shown in FIG. 6, where the low-noise amplifier 190 has been bypassed, i.e. the second loopback path has been used. FIG. 6 depicts the EVM behaviour of several components in this test signal path at various modified performance levels relative to the nominal performance of these components using a test signal comprising a random bit pattern. The displayed component performance in FIG. 6 at the various performance levels is, from left to right, the gain of demodulating mixer 188, the noise figure of demodulating mixer 188, the gain imbalance of the modulating mixer 168, the phase imbalance of the modulating mixer 168, the loss in filter 186 and the DC offset in offset block 194. The horizontal line once more depicts the EVM behaviour of the golden device when using this loopback path.

It will be apparent that, compared to FIG. 5, the deviations from the nominal behaviour of the performance parameters of these components lead to a much more pronounced deviation in the EVM behaviour, thus increasing the confidence level of the detection of faults leading to the deviation of nominal behaviour of the components shown in FIG. 6. Typically, the deviation of the performance of the components, e.g. deviation in gain, or deviation in noise figure, is caused by parametric faults, i.e. process parameter values that lie outside an acceptable value window. Consequently, the detection of performance deviation by means of EVM deviation can be used to detect parametric faults in these components.

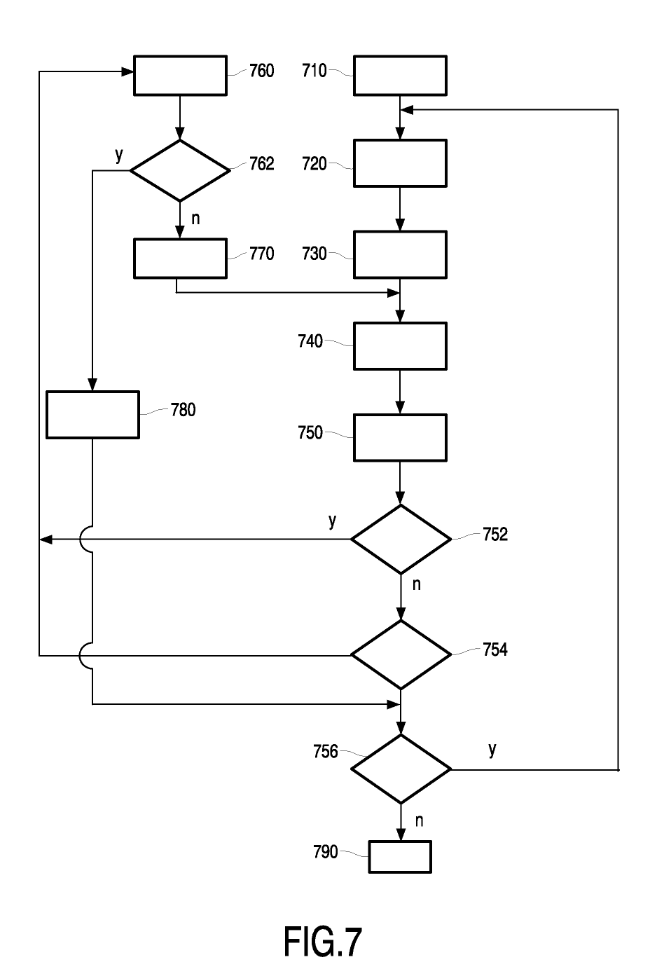

The test method applied to the electronic device 100 and implemented by the BIST arrangement on the baseband processor architecture 120 utilizes the above findings, i.e. the test pattern specific sensitivity of the EVM value to parametric faults. FIG. 7 shows a flowchart of the test method of the present invention. In a first step 710, a plurality of records is provided, each record comprising the deviation of the EVM for a response to a test signal caused by a specific parametric fault in a specific component of the electronic device 100 using a specific loopback path. An example of such a record is given below.

Gain Demodulator 188 (Loopback path 2)

| | |
|---|---|
| Random | Yes |
| All ‘0’s | No |
| 25% ‘0’s | No |
| 75% ‘0’s | Yes |
| All ‘1’s | Yes |

The record lists the expected deviation in the response to a bit pattern based test signal routed via the loopback path from the output of the power amplifier 170 to the input of demodulating mixer 188 in case the demodulating mixer 188 contains a parametric fault causing a deviation in the gain of the mixer. The left hand column indicates the nature of the test signal, and the right column indicates whether or not the EVM deviation detected by QSPK calculation block 128 is expected to exceed a predefined threshold. Preferably, the test signal dependent EVM behaviour of each performance parameter of each component in the test signal path that is likely to be sensitive to parametric variations will be mapped in separate tables for each loopback path.

It will be apparent that several variations to a record structure can be made. For instance, rather than giving a Boolean type response in the right hand column (threshold exceeded), an actual value or value window of the

EVM deviation may be given. In addition, a performance parameter, e.g. the gain of demodulating mixer 188, may comprise a number of tables for the different off-nominal values of the parameter, e.g. separate tables for a gain value that has a deviation of −20%, −10%, +10%, +20% compared to the nominal gain. The latter may be advantageous to both identify as well as quantify a parametric fault. The values in the separate tables may be obtained by simulation or by determining the EVM behaviour of an electronic device 100 into which specific parametric faults have been injected. The records may be implemented in the BIST arrangement of the baseband processor architecture 120 by means of look-up tables or another suitable form of data storage, e.g. a suitably partitioned memory.

In a next step 720, the loopback path to be used is selected. For instance, the loopback path between the output of the power amplifier 170 and the low-noise amplifier 190 may be selected for detecting parametric faults in the low-noise amplifier 190, as explained in conjunction with FIG. 5. This is followed by step 730, in which an initial test signal is generated by test pattern generator 122 and the IFFT block 124 and injected into the upconversion stage 160. The initial test signal is typically generated from a bit pattern that is known to sensitize the largest number of parametric faults in the test signal path. This is usually the case for a random bit pattern. In step 740, the response to the test signal is received by the baseband processor architecture 120 and the deviation of the response from its expected value is detected in step 750. This may for instance be done by calculating the EVM of the response.

If the deviation does not exceed a predefined threshold, which is checked in step 752, and if the test signal is the initial test signal, as checked in step 754, no parametric fault has been detected and the test may be ended in step 790 if no further loopback path is to be tested, as checked in step 756. In case another loopback path is to be tested, the test flow jumps back to step 720.

If the deviation does exceed a predefined threshold, as checked in step 752, the test flow progresses to step 760 in which those records from the plurality of records provided in step 710 are selected that have a recorded response to the initial test signal exceeding the predefined threshold. In other words, in step 760 those parametric faults are selected that are known to cause the response to the initial test signal to exceed the predefined threshold. Subsequently, it is checked in step 762 if the selection of tables made in step 760 comprises more than one record. If the selection comprises only one record, this means that it is known which parametric fault in which component, e.g. a gain impairment in demodulating mixer 188, has caused the deviation of the response of its intended value. The fault is reported in step 780 after which the test method is forwarded to step 756.

If, on the other hand, the selection of tables comprises more than one member, i.e. if more than one parametric fault may be responsible for the deviation of the response received in step 740, a further test signal is generated in step 770, e.g. by test pattern generator 122 and IFFT function 124, and injected into the upconversion stage 160. The further test signal may be generated taking into consideration the shape of the initial test signal generated in step 730 in order to maximize the difference between the initial test signal and the further test signal, e.g. an initial test signal derived from a random bit pattern may be followed by a further test signal derived from an all ‘1’s or all ‘0’s bit pattern because it is most likely that such a choice maximizes the difference between the initial and further test signal. Alternatively, the further test signal may be selected based on an evaluation of the tables selected in step 760, because it will be apparent from these tables which bit pattern will have the largest differentiating effect.

Next, steps 740, 750, 752 and 754 are repeated, after which the determined deviation of the response to the further test signal is used to further prune the tables selected in step 760 by removing those tables from the selection that do not match the determined response deviation to the further test signal. This process is repeated until the selection of tables comprises a single table, after which the corresponding parametric fault is reported in step 780 and the test flow is forwarded to step 756.

It will be appreciated that various steps of the method of the present invention are preferably implemented on the baseband processor arrangement 120 in software, although this is not strictly necessary. Since it will be evident to the skilled person how the method of the present invention may be implemented on the baseband processor 120, such an implementation has not been discussed in detail for the sake of brevity.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to an advantage.

1. An electronic device comprising:
a transceiver stage for communicating signals between the electronic device and a further device; and
a baseband processor arrangement implementing a built-in self test arrangement for, in a test mode:
forwarding a test signal to the transceiver stage;
receiving a response to the test signal; and
determining, for the response, a deviation from an expected response to the test signal;
characterized in that the built-in self test arrangement further comprises:
a plurality of records, each record comprising predetermined response deviations to different test signals caused by a parametric fault; and
means for selecting those records from the plurality of records for which the predetermined response deviation corresponds to the deviation of the received response.

2. An electronic device as claimed in claim 1, wherein the built-in self test arrangement is further arranged to:
forward a further test signal to the transceiver stage;
receive a further response to the further test signal;
determine, for the further response, a further deviation from the expected further response to the further test signal; and
deleting those records from the selection of records that comprise a predetermined deviation from the expected response to the further test signal that is different than the determined further deviation.

3. An electronic device as claimed in in claim 1, further comprising:
a frequency upconversion stage for upconverting the frequency of signals from the baseband processor to the transceiver stage;
a frequency downconversion stage for downconverting the frequency of signals from the transceiver stage to the baseband processor; and
a loopback path from a part of the frequency upconversion stage to a corresponding part of the frequency downconversion stage.

4. An electronic device as claimed in claim 3, wherein:
the frequency upconversion stage comprises an upsampling unit, a filter, a signal modulator and an amplifier coupled in series;
the frequency downconversion stage comprises an amplifier, a signal demodulator, a filter and a downsampling unit coupled in series; and
the electronic device comprises at least one of the following loopback paths:
a first loopback path coupling the output of the amplifier in the upconversion stage to the input of the amplifier in the downconversion stage;
a second loopback path coupling the output of the amplifier in the upconversion stage to the input of the signal demodulator in the downconversion stage; and
a third loopback path coupling the output of the filter in the upconversion stage to the input of the filter in the downconversion stage.

5. An electronic device as claimed in claim 3, wherein each loopback path comprises a test attenuator.

6. An electronic device as claimed in claim 3, wherein the frequency upconversion stage and the frequency downconversion stage are arranged to process complex signals, and wherein each loopback path comprises a pair of subpaths for coupling the respective signal paths of the I and Q components of the complex signal through the frequency upconversion stage to the respective signal paths of the I and Q components of the complex signal through the frequency downconversion stage.

7. An electronic device as claimed in claim 1, wherein the built-in self test arrangement is arranged to calculate the error vector magnitude of the response to the test signal.

8. A method of testing an electronic device comprising:
a transceiver stage for communicating signals between the electronic device and a further device; and
a baseband processor arrangement,
the method comprising:
forwarding a test signal to the transceiver stage;
receiving a response to the test signal; and
determining, for the response, the deviation from the expected response to the test signal;
characterized by further comprising:
providing a plurality of records, each record comprising predetermined response deviations to different test signals caused by a parametric fault; and
selecting those records from the plurality of records for which the predetermined response deviation corresponds to the deviation of the received response.

9. A method as claimed in claim 8, further comprising:
forwarding a further test signal from the baseband processor to the transceiver stage;
receiving a further response to the further test signal at the baseband processor;
determining, for the further response, a further deviation from the expected further response to the further test signal; and
deleting those records from the selection of records that comprise a predetermined deviation from the expected response to the further test signal that is different to the determined further deviation.

10. A method as claimed in claim 8, wherein the electronic device further comprises:
a frequency upconversion stage for upconverting the frequency of signals from the baseband processor to the transceiver stage;
a frequency downconversion stage for downconverting the frequency of signals from the transceiver stage to the baseband processor;
the method further comprising:
providing a loopback path from the frequency upconversion stage to a corresponding part of the frequency downconversion stage.

11. A method as claimed in claim 10, wherein the frequency upconversion stage comprises an upsampling unit, a filter, a signal modulator and an amplifier coupled in series;
the frequency downconversion stage comprises an amplifier, a signal demodulator, a filter and a downsampling unit coupled in series; and
wherein the step of providing a loopback path comprises providing at least one of the following loopback paths:
a first loopback path coupling the output of the amplifier in the upconversion stage to the input of the amplifier in the downconversion stage;
a second loopback path coupling the output of the amplifier in the upconversion stage to the input of the signal demodulator in the downconversion stage; and
a third loopback path coupling the output of the filter in the upconversion stage to the input of the filter in the downconversion stage.
